(19) United States
(12) Patent Application Publication
(10) Pub. No.: US 2026/0047379 A1
(43) Pub. Date: Feb. 12, 2026

(54) METHOD AND DEVICE FOR CONTROLLING CHIP PITCH BASED ON FILM PIERCING

(71) Applicant: Guangdong University of Technology, Guangzhou (CN)

(72) Inventors: Yun CHEN, Guangzhou (CN); Xiangyuan LUO, Guangzhou (CN); Li MA, Guangzhou (CN); Jiawei XIAO, Guangzhou (CN); Zilin HE, Guangzhou (CN); Maoxiang HOU, Guangzhou (CN); Xin CHEN, Guangzhou (CN)

(21) Appl. No.: 19/364,642

(22) Filed: Oct. 21, 2025

(30) Foreign Application Priority Data
Nov. 4, 2024 (CN) 202411561171.1

(51) Int. Cl. H01L 21/67; G06T 7/00; G06T 7/70

(52) U.S. Cl. CPC H01L 21/67132; G06T 7/0004; G06T 7/70; G06T 2207/30148

(57) ABSTRACT

A chip pitch control method is provided, in which a first position matrix is generated, and a target matrix of the chips is constructed according to the first position matrix; a first displacement vector set of the chips is constructed; a second displacement vector set is generated, and a unit displacement vector each chip corresponding to a pinhole is obtained by quadratic spline interpolation in combination with the second displacement vector set; an objective function is iterated, and pinhole coordinates are simultaneously adjusted; the number of pinholes is adjusted, and compared with the number of chips; the target matrix is adjusted according to comparison results, and step (S2) or step (S6) is performed; a needle is controlled to pierce a back film according to the adjusted pinhole coordinates. A chip pitch control device is also provided.

### CROSS-REFERENCE TO RELATED APPLICATIONS

This application claims the benefit of priority from Chinese Patent Application No. 202411561171.1, filed on Nov. 4, 2024. The content of the aforementioned application, including any intervening amendments thereto, is incorporated herein by reference in its entirety.

### TECHNICAL FIELD

This application relates to chip transfer and packaging technologies, and more particularly to a method and device for controlling chip pitch based on film piercing.

### BACKGROUND

After the routine wafer dicing operation, the chip pitch is still very small, and to facilitate subsequent processing procedures, it is necessary to stretch a blue film or ultraviolet film (UV film) on the backside to increase the chip pitch, which is called wafer expansion. Conventional wafer expanders adopt a tape-pushing platform with lifting and heating functions to preheat the backside tape (blue tape or UV tape) for softening, and stretch and secure the tape via an expansion ring, so as to complete the wafer expansion process. However, the uneven heating and uneven stress distribution of the backside tape during the rising process of the platform will make the chip pitch irregular after the expansion, which will further lead to a decline in the transfer precision.

Therefore, there is an urgent need to develop an approach to adjust the chip distribution on the wafer expansion ring to solve the problems of uneven post-expansion chip pitch and poor transfer precision in the prior art.

### SUMMARY

An object of the present disclosure is to provide a method and device for controlling chip pitch based on film piercing to address the problems of uneven post-expansion chip pitch and poor transfer precision in the prior art.

In order to achieve the objective, the present disclosure adopts the following technical solutions.

In a first aspect, the present disclosure provides a method for controlling chip pitch based on film piercing, comprising:
(S1) generating a first position matrix according to position coordinates of each of a plurality of chips before film piercing, and constructing a target matrix of the plurality of chips according to the first position matrix;
(S2) constructing a first displacement vector set of the plurality of chips according to the first position matrix and the target matrix;
(S3) generating a second displacement vector set according to position coordinates of each of the plurality of chips after the film piercing and the first position matrix; and obtaining a unit displacement vector of each of the plurality of chips corresponding to a pinhole based on a quadratic spline interpolation method and the second displacement vector set;
(S4) iterating an objective function according to unit displacement vectors of the plurality of chips and the first displacement vector set, and simultaneously adjusting coordinates of the pinhole;
(S5) adjusting the number of the pinhole according to a value of the objective function and an expected value; comparing the number of the pinhole with the number of the plurality of chips; and according to comparison results, adjusting the target matrix and returning to step (S2), or proceeding to step (S6); and
(S6) controlling a needle to pierce a back film according to adjusted coordinates of the pinhole.

In an embodiment, step (S1) comprises:
calculating the position coordinates of each of the plurality of chips before the film piercing with a center of the wafer expansion ring as an origin;
marking the position coordinates of each of the plurality of chips to generate the first position matrix; and
calculating an average chip pitch in a X-axis direction and an average chip pitch in a Y-axis direction based on the first position matrix, respectively; and constructing the target matrix of the plurality of chips based on the average chip pitch in the X-axis direction and the average chip pitch in the Y-axis direction with the origin as a center of the target matrix.

In an embodiment, the method, furthering comprising:
after step (S3), determining whether it is needed to replace the needle through steps of:
obtaining a displacement vector of a first chip in the second deformation vector set in the X-axis direction;
if a length corresponding to the displacement vector of the first chip in the X-axis direction is greater than the average chip pitch in the X-axis direction or the average chip pitch in the Y-axis direction, replacing the wafer expansion ring, replacing the needle with another one with a smaller diameter, and returning to step (S1);
if the length corresponding to the displacement vector of the first chip in the X-axis direction is less than the average chip pitch in the X-axis direction or the average chip pitch in the Y-axis direction and greater than one fifth of the average chip pitch in the X-axis direction or the average chip pitch in the Y-axis direction, proceeding to step (S4); and
if the length corresponding to the displacement vector of the first chip in the X-axis direction is no more than one fifth of the average chip pitch in the X-axis direction or the average chip pitch in the Y-axis direction, replacing the wafer expansion ring, replacing the needle with another one with a smaller diameter, and returning to step (S1).

In an embodiment, the step of obtaining the unit displacement vector of each of the plurality of chips corresponding to the pinhole based on the quadratic spline interpolation method and the second displacement vector set comprises:
obtaining the position coordinates of each of the plurality of chips before the film piercing and the displacement vector of each of the plurality of chips in the second displacement vector set; and
calculating coefficients of a spline curve between every two of the plurality of chips by using the quadratic spline interpolation method, satisfying the following relationship:

$$Δ {x}_{b i j} = {a}_{i} {x}_{1 i j}^{2} + {b}_{i} {x}_{1 ij} + {c}_{i} ;$$

wherein Δx_{bij} represents a displacement vector of a chip in an i-th row and a j-th column of the second displacement vector set; x₁ᵢⱼ represents an X-axis coordinate of the chip in the i-th row and the j-th column before the film piercing; and aᵢ, bᵢ and cᵢ represent the coefficients of the spline curve between every two of the plurality of chips.

In an embodiment, the step of obtaining the unit displacement vector of each of the plurality of chips corresponding to the pinhole based on the quadratic spline interpolation method and the second displacement vector set further comprises:
obtaining a distance between each of the plurality of chips and the pinhole;
calculating a displacement of each of the plurality of chips after the film piercing according to the coefficients of the spline curve between every two of the plurality of chips and the distance between each of the plurality of chips and the pinhole, expressed as:

$$Δ x = {a}_{i} {d}^{2} + {b}_{i} d + {c}_{i} ;$$

wherein Δx represents the displacement of each of the plurality of chips after the film piercing; aᵢ, bᵢ and cᵢ represent the coefficients of the spline curve between every two of the plurality of chips; and d represents the distance between each of the plurality of chips and the pinhole; and
constructing the unit displacement vector based on the displacement of each of the plurality of chips after the film piercing and a direction from the pinhole to a corresponding one of the plurality of chips.

In an embodiment, the step of iterating the objective function according to unit displacement vectors of the plurality of chips and the first displacement vector set, and simultaneously adjusting the coordinates of the pinhole comprises:
subjecting the unit displacement vectors to addition to generate a total displacement vector;
calculating an average distance between the plurality of chips and the target matrix according to the total displacement vector and the first displacement vector set, expressed as:

$$f = \frac{1}{n} \sum ‖ C - Δ A ‖ ;$$

wherein ƒ represents the objective function; C represents the total displacement vector; n represents the number of the plurality of chips; and AA represents the first displacement vector set; and
adjusting the coordinates of the pinhole until the objective function ƒ no longer changes, and recording adjusted coordinates of the pinhole.

In some embodiments, in step (S5), the step of adjusting the number of the pinhole according to the value of the objective function and the expected value comprises:
setting the expected value;
if the value of the objective function is not less than the expected value, increasing the number of the pinhole; and
if the value of the objective function is less than the expected value, keeping the number of the pinhole unchanged.

In some embodiments, the step of comparing the number of the pinhole with the number of the plurality of chips, and according to comparison results, adjusting the target matrix and returning to step (S2), or proceeding to step (S6) comprises:
if the number of the pinhole is less than one percent of the number of the plurality of chips, executing step (S6); and
if the number of the pinhole is not less than one percent of the number of the plurality of chips, increasing a chip pitch in the target matrix and returning to step (S2).

In a second aspect, the present disclosure provides a device for controlling chip pitch based on film piercing, comprising:
a vision module;
an operation module; and
a movement module;
wherein the vision module is configured to capture images of a plurality of chips and send the images of the plurality of chips to the operation module;
the operation module is configured to receive the images of the plurality of chips from the vision module, calculate coordinates of the plurality of chips with a center of a wafer expansion ring as an origin, and perform steps of:
(S1) generating a first position matrix according to position coordinates of each of the plurality of chips before the film piercing, and constructing a target matrix of the plurality of chips according to the first position matrix;
(S2) constructing a first displacement vector set of the plurality of chips according to the first position matrix and the target matrix;
(S3) generating a second displacement vector set according to position coordinates of each of the plurality of chips after the film piercing and the first position matrix; and obtaining a unit displacement vector of each of the plurality of chips corresponding to a pinhole based on a quadratic spline interpolation method and the second displacement vector set;
(S4) iterating an objective function according to unit displacement vectors of the plurality of chips and the first displacement vector set, and simultaneously adjusting coordinates of the pinhole; and
(S5) adjusting the number of the pinhole according to a value of the objective function and an expected value; comparing the number of the pinhole with the number of the plurality of chips; and according to comparison results, adjusting the target matrix and returning to step (S2), or sending adjusted coordinates of the pinhole to the movement module; and
the movement module is configured to receive the adjusted coordinates of the pinhole from the operation module, and control a needle to pierce a back film according to the adjusted coordinates of the pinhole.

Compared to the prior art, this application has the following beneficial effects.

The present disclosure adopts the quadratic spline interpolation method to smooth new positions of individual chips, such that the non-linear characteristics of film deformation can be captured, thereby improving calculation accuracy of the unit displacement vector and facilitating the chip pitch control.

The objective function is optimized by iteration, such that coordinates of the pinhole can be continuously adjusted to find an optimal piercing position, thereby making the chip pitch gradually approach an expected condition and reducing errors caused by static arrangement.

Based on the evaluation of the objective function, the number of pinholes can be flexibly adjusted to prevent failure in meeting the meet requirements of the chip pitch control or excessive time consumption for solving the pinhole coordinates. Moreover, excessive pinholes may damage an internal stress on the wafer expansion ring, leading to changes in overall mechanical properties of the wafer expansion ring and making it unusable for the subsequent procedures.

### BRIEF DESCRIPTION OF THE DRAWINGS

In order to illustrate the technical solutions in the embodiments of the present disclosure or in the prior art more clearly, the accompanying drawings needed in the description of the prior art or the embodiments of the present disclosure will be briefly described below. Obviously, presented in the accompany drawings are merely some embodiments of the present disclosure. Other accompanying drawings can also be obtained by those skilled in the art based on these accompanying drawings without paying creative effort.

FIG. 1 is a flow chart of a chip pitch control method based on film piercing according to an embodiment of the present disclosure;

FIG. 2 schematically illustrates a chip pitch control device based on the film piercing according to an embodiment of the present disclosure; and

FIG. 3 schematically shows a device applied to the chip pitch control method according to an embodiment of the present disclosure.

In the figures: 1—wafer expansion ring platform; 2—vision module; 21—light source; 22—image acquisition unit; 3—operation module; 4—movement module; 5—wafer expansion ring; 51—chip; 52—back film; and 6—needle.

### DETAILED DESCRIPTION OF EMBODIMENTS

The embodiments of the present disclosure will be described in detail below. Examples of the embodiments are shown in the accompanying drawings, where the same or similar labels represent the same or similar components or components with the same or similar functions. The embodiments described below with reference to the accompanying drawings are merely illustrative of the disclosure, and are not intended to limit the present disclosure.

As used herein, it should be noted that orientations or positional relationships indicated by terms “center”, “longitudinal”, “transverse”, “length”, “width”, “thickness”, “up”, “down”, “left”, “right”, “upright”, “horizontal”, “top”, “bottom”, “inside”, “outside”, “axis”, “radial” and “circumferential” are based on those shown in the accompanying drawings. These terms are merely used to facilitate the description of the present disclosure and simplify the description, and are not intended to indicate or imply that the device or component referred to must have a specific orientation, or be constructed and operated in a specific orientation. Therefore, they should not be understood as a limitation of the present disclosure.

Furthermore, as used herein, the terms “first” and “second” are merely for illustrative purposes, and should not be construed as indicating or implying the relative importance or the quantity of the technical features involved. Therefore, features defined by “first” or “second” may explicitly or implicitly indicate the inclusion of at least one of such features. As used herein, unless otherwise specified, the term “a plurality of” means two or more.

In the description of the present disclosure, it should be noted that, unless otherwise clearly specified and limited, the terms “installation”, “link”, and “connection” should be interpreted in a broad sense. For example, it can be fixed connection, detachable connection, or integral connection; it can be direct connection, indirect connection through an intermediate medium, or internal communication between two components. For those of ordinary skill in the art, the specific meanings of the above terms in the present disclosure can be understood according to the specific context.

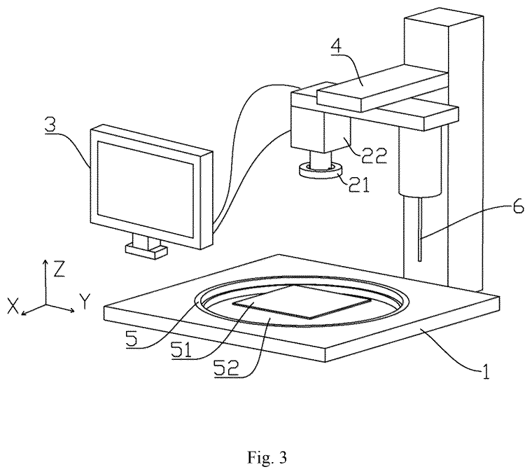

Referring to FIG. 3, the present disclosure provides a device for controlling chip pitch, including a wafer expansion ring platform 1, a vision module 2, an operation module 3 and a movement module 4, where the wafer expansion platform 1 is configured to receive a wafer expansion ring 5 after film expansion.

The vision module 2 includes a light source 21 and an image acquisition unit 22. The light source 21 is configured to emit light that can be clearly reflected by a chip 51. The image acquisition unit 22 is arranged above a wafer, and is configured to take pictures of chips 51 on the wafer.

The operation module 3 is connected to the vision module 2, and is configured to calculate coordinates of the plurality of chips 51, and control the movement module 4 to move to the film piercing position.

The movement module 4 is configured to move the image acquisition unit 22 and a needle 6.

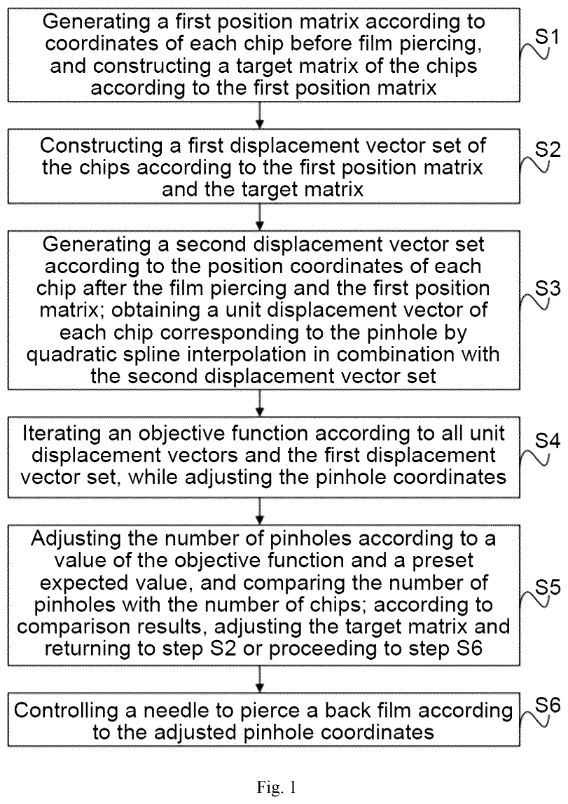

As shown in FIG. 1, an embodiment of the present disclosure provides a method for controlling chip pitch based on film piercing, including the following steps.

(S1) A first position matrix is generated according to position coordinates of individual chips before film piercing, and a target matrix of the plurality of chips is constructed according to the first position matrix.

In this embodiment, the wafer expansion ring 5 is placed on the wafer expansion ring platform 1. After activating the light source 21, pictures of the wafer expansion ring 5 are taken via the image acquisition unit 22, and sent to the operation module 3. An actual position coordinate (x₁ᵢⱼ,y₁ᵢⱼ) of each of the plurality of chips is calculated with a center of the wafer expansion ring 5 as an origin, where i represents the chip row index, and j represents the chip column index. A matrix A₁ represents the actual position coordinates of the plurality of chips, and the first position matrix records the actual position coordinate of each of the plurality of chips before film piercing. An expected position of each of the plurality of chips is set via a target matrix to minimize interference between two adjacent chips to the greatest extent. Thus, the target matrix is calculated according to the expected chip pitch and distribution. The positions of each of the plurality of chips in an expected state are calculated by setting an expected chip pitch, and the coordinate of each of the plurality of chips in the target matrix is set as (x₂ᵢⱼ,y₂ᵢⱼ).

(S2) A first displacement vector set of the plurality of chips is constructed according to the first position matrix and the target matrix.

The first displacement vector set is calculated by differences between the first position matrix and the target matrix. Each of the plurality of displacement vectors represents an offset between the actual position of each of the plurality of chips and the expected position of each of the plurality of chips. The first displacement vector set AA includes the plurality of displacement vectors (Δxᵢⱼ,Δyᵢⱼ), and the direction of each of the plurality of displacement vectors is from the actual position of each of the plurality of chips to the expected positions of each of the plurality of chips. The displacement vector contributes to determining how to adjust the chip in practical operation to reach the expected position.

(S3) A second displacement vector set is generated according to the position coordinates of each of the plurality of chips after the film piercing and the first position matrix. A unit displacement vector of each of the plurality of chips corresponding to a pinhole are obtained based on a quadratic spline interpolation method and the second displacement vector set.

After an instruction is sent to the movement module 4, the needle 6 is controlled to drop down at the origin and pierce the back film 52 (blue film or ultraviolet film (UV film)). After piercing film, each of the plurality of chips moves due to film displacement, and the position coordinates of each of the plurality of chips are recorded. The displacement vectors (Δx_{bij},Δy_{bij}) of each of the plurality of chips from the actual positions before the film piercing to the actual positions after the film piercing are calculated by combining with the first position matrix. AB represents the second displacement vector set. The quadratic spline interpolation is configured to smooth new positions of each of the plurality of chips, thereby calculating the unit displacement vectors of each of the plurality of chips. The quadratic spline interpolation is a mathematic method to construct a smooth curve among known points and capture non-linear properties of the film displacement. The effect of the film on the positions of each of the plurality of chips can be described more accurately by interpolating the new positions.

(S4) An objective function is iterated according to unit displacement vectors of the plurality of chips and the first displacement vector set, and coordinates of the pinhole are simultaneously adjusted during the iteration process.

Firstly, the objective function is defined to measure differences between the displacement vector formed by a combined action of all pinholes on each of the plurality of chips and the first displacement vector set. When iterating, a value of the objective function is increasingly smaller, indicating that the actual position of each of the plurality of chips is increasingly closer to the expected positions of each of the plurality of chips. This step optimizes the value of the objective function through an iterative algorithm and continuously adjusts the coordinates of the pinhole. Each iteration is updated based on actual displacement vector and the expected position to find optimal position of the pinhole, thereby achieving an expected distribution of the chip.

(S5) The number of the pinhole is adjusted according to the value of the objective function and an expected value. The number of the pinhole is compared with the number of the plurality of chips. According to comparison results, the target matrix is adjusted, and returning to step (S2), or (S6) is performed.

Subsequently, the expected value is set by combining subsequent steps to evaluate an actual value of the objective function. If the value of the objective function fails to expectation, the number of pinholes is adjusted. If there are excessive pinholes, a solution time for the coordinates of the pinhole is greatly prolonged. Moreover, excessive pinholes can damage an internal stress on the wafer expansion ring 5, leading to changes in overall mechanical property of the wafer expansion ring 5 and making it unusable for the subsequent procedures. Thus, the target matrix is adjusted according to comparison results, and returning to step (S2), or step (S6) is performed.

(S6) A needle is controlled to pierce the back film 52 according to adjusted coordinates of the pinhole.

Based on the adjusted coordinates of the pinhole, movement paths and piercing forces of the needle 6 are controlled. By precisely controlling the positions and movements of the needle, the film is ensured to be pierced as uniformly as possible, thereby reducing inconsistency of the chip pitch. Through effective piercing operation, the film is prone to undergoing a controllable displacement, ultimately achieving the expected distribution of the chips on carrier.

The present disclosure adopts the quadratic spline interpolation method to smooth the new position of the each of the plurality of chips and capture the non-linear property of the film displacement, thereby improving a calculation accuracy of the unit displacement vector and facilitating to the pitch control.

The coordinates of the pinhole are continuously adjusted based on iterating and optimizing the objection function to find an optimal piercing position, ensuring the chip pitch to close gradually close toward an expected condition and reducing errors caused by a static arrangement.

Based an evaluation of the objective function, the number of the plurality of pinholes is flexibly adjusted to avoid a situation where the number of the plurality of pinholes fails to meet the requirements of the chip pitch control or the solution time for the pinhole coordinates is greatly extended. Moreover, excessive pinholes can damage an internal stress on the wafer expansion ring 5, leading to changes in the overall mechanical property of the wafer expansion ring 5 and making it unusable for the subsequent procedures.

In some embodiments, step (S1) includes the following steps.

The position coordinates of each of the plurality of chips before the film piercing with a center of the wafer expansion ring as an origin.

The first position matrix is generated by marking the position coordinates of each of the plurality of chips.

An average chip pitch in an X-axis direction and an average chip pitch in a Y-axis direction are calculated based on the first position matrix, respectively. The target matrix of the plurality of chips is constructed based on the average chip pitch in the X-axis direction and the average chip pitch in the Y-axis direction with the origin as a center of the target matrix.

In some embodiments, the center of the wafer expansion ring 5 is defined as the origin (0,0), where the wafer expansion ring is usually arranged in a center of the wafer to provide a stable reference point, and make subsequent calculations more consistent with orientations. The coordinates of each of the plurality of chips are calculated via the operation module 3 based on images obtained from the vision module 2. The coordinates of each of the plurality of chips are recorded in a form of (x, y), representing a distance from the origin to the coordinate of each of the plurality of chips. The matrix (the first position matrix) includes the position coordinates of the plurality of chips to facilitate to the subsequent calculations and analyses. X-coordinates and Y-coordinates of the plurality of chips in the first position matrix are respectively calculated to obtain the average chip pitch in the X-axis direction and the average chip pitch in the Y-axis direction. The target matrix is constructed based on the average chip pitch in the X-axis direction and the average chip pitch in the Y-axis direction with the origin as a center of the target matrix. Each position in the target matrix represents a position where each of the plurality of chips is arranged under the expected condition. Random errors of measurements of the position of each of the plurality of chips are eliminated by calculating the average chip pitch, thereby allowing the chip pitch to be better controlled and more uniform.

In some embodiments, after step (S3), the step of determining whether it is needed to replace the needle includes obtaining a displacement vector of a first chip in the second deformation vector set in the X-axis direction.

If a length corresponding to the displacement vector of the first chip in the X-axis direction is greater than the average chip pitch in the X-axis direction or the average chip pitch in the Y-axis direction, the wafer expansion ring 5 is replaced, and the needle is replaced with another one with a smaller diameter, thereby returning to step (S1).

If the length corresponding to the displacement vector of the first chip in the X-axis direction is less than the average chip pitch in the X-axis direction or the average chip pitch in the Y-axis direction and greater than one fifth of the average chip pitch in the X-axis direction or the average chip pitch in the Y-axis direction, thereby proceeding to step (S4).

If the length corresponding to the displacement vector of the first chip in the X-axis direction is no more than one fifth of the average chip pitch in the X-axis direction or the average chip pitch in the Y-axis direction, the wafer expansion ring 5 is replaced, and the needle is replaced with another one with a smaller diameter, thereby returning to step (S1).

In some embodiments, the displacement vector Δx_{b11} of the first chip in the second displacement vector set in the X-axis direction is usually a maximum value in the second displacement vector set. If the length corresponding to the displacement vector of the first chip in the X-axis direction is greater than the average chip pitch in the X-axis direction or the average chip pitch in the Y-axis direction, a diameter of the needle 6 is considered to be oversize, and the needle is replaced with another one with a smaller diameter and the wafer expansion ring 5 is also replaced, thereby returning to step (S1).

If the length corresponding to the displacement vector of the first chip in the X-axis direction is less than the average chip pitch in the X-axis direction or the average chip pitch in the Y-axis direction and greater than one fifth of the average chip pitch in the X-axis direction or the average chip pitch in the Y-axis direction, the diameter of the needle is considered to be ordinary, thereby proceeding to step (S4).

If the length corresponding to the displacement vector of the first chip in the X-axis direction is no more than one fifth of the average chip pitch in the X-axis direction or the average chip pitch in the Y-axis direction, the diameter of the needle is considered to be undersize. The number of the pinhole for the chip pitch control is excessive, such that the positions of pinholes are difficult to be calculated, requiring too long time. Consequently, the needle 6 is replaced with another one with a smaller diameter and the wafer expansion ring 5 is also replaced, thereby returning to step (S1). By comparing the displacement vector with the average chip pitch, the suitability of the needle diameter is accurately determined, thereby ensuring the accuracy and stability of chip processing. Unsuitable needles and the wafer expansion ring 5 can be quickly identified and replaced to avoid processing errors and time waste caused by improper tools.

In an embodiment, the step of obtaining the unit displacement vector of each of the plurality of chips corresponding to the pinhole based on the quadratic spline interpolation method and the second displacement vector set is performed through the following steps.

The position coordinates of each of the plurality of chips before the film piercing and the displacement vector of each of the plurality of chips in the second displacement vector set are obtained.

Coefficients of a spline curve between every two of the plurality of chips are calculated by using the quadratic spline interpolation method, satisfying the following relationship:

$$Δ {x}_{b i j} = {a}_{i} {x}_{1 i j}^{2} + {b}_{i} {x}_{1 ij} + {c}_{i} ;$$

where Δx_{bij} represents the displacement vector of a chip in an i-th row and a j-th column of the second displacement vector set; x₁ᵢⱼ represents an X-axis coordinate of the chip in the i-th row and the j-th column before the film piercing; and aᵢ, bᵢ and cᵢ represent the coefficients of the spline curve between every two of the plurality of chips.

In an embodiment, the film displacement after a single film piercing usually exhibits as a ray about a rotation of the pinhole. Consequently, the unit displacement vector is constructed based on the plurality of the film displacement vectors in the second displacement vector set along the positive direction of the X-axis starting from the origin. The coefficients of the spline curve between every two of the plurality of chips are calculated via an equation

$$Δ {x}_{b i j} = {a}_{i} {x}_{1 i j}^{2} + {b}_{i} {x}_{1 ij} + {c}_{i} ,$$

where Δx_{bij} is taken in the displacement vectors of each of the plurality of chips in the X-axis direction and x₁ᵢⱼ is taken in the actual position coordinates of each of the plurality of chips before the film piercing. The quadratic spline is fitted to the film displacement vector in the positive direction of the X-axis. The unit displacement vector is a displacement field formed by rotating the quadratic spline around the pinhole position. Through the interpolation, a smooth variation of the displacement vectors among each of the plurality of chips is obtained, avoiding sudden changes or discontinuities and ensuring a physical meaning of data.

In an embodiment, the step of obtaining the unit displacement vector of each of the plurality of chips corresponding to the pinhole based on the quadratic spline interpolation method and the second displacement vector set further includes the following steps.

A distance between each of the plurality of chips and the pinhole is obtained.

A displacement of each of the plurality of chips after the film piercing is calculated according to the coefficients of the spline curve between every two of the plurality of chips and the distance between each of the plurality of chips and the pinhole, expressed as:

$$Δ x = {a}_{i} {d}^{2} + {b}_{i} d + {c}_{i} ;$$

where Δx represents the displacement of each of the plurality of chips after the film piercing; aᵢ, bᵢ and cᵢ represent the coefficients of the spline curve between every two of the plurality of chips; and d represents the distance between each of the plurality of chips and the pinhole.

The unit displacement vector is constructed based on the displacement of each of the plurality of chips after the film piercing and a direction from the pinhole to a corresponding one of the plurality of chips is also constructed.

In an embodiment, a calculated displacement of each of the plurality of chips after the film piercing is configured as a length of the unit displacement vector. The unit displacement vector is defined as a vector with a certain magnitude in a specific direction.

The unit displacement vector includes a displacement information reflecting movement degree of each of the plurality of chips, and a direction information reflecting displacement of each of the plurality of chips, where the direction information represents a direction from the pinhole to each of the plurality of chips.

By substituting a value of the distance d, the corresponding displacement Δx is obtained. Smooth displacement changes are generated between each of the plurality of chips, rather than simple linear interpolation, thereby more truly reflecting the actual displacement after the film piercing.

In an embodiment, the step of iterating the objective function according to unit displacement vectors of the plurality of chips and the first displacement vector set, and simultaneously adjusting the coordinates of the pinhole is performed through the following steps.

The unit displacement vectors are subjected to addition to generate a total displacement vector.

An average distance between all the plurality of chips and the target matrix is calculated according to the total displacement vector and the first displacement vector, which expresses as:

$$f = \frac{1}{n} \sum ‖ C - Δ A ‖ ;$$

where ƒ represents the objective function; C represents the total displacement vector, n represents the number of the plurality of chips, and AA represents the first displacement vector set.

The coordinates of the pinhole are adjusted until the objective function ƒ no longer changes, and the adjusted coordinates of the pinhole are recorded.

In an embodiment, the objective function ƒ is configured to measure the differences between the total displacement vector C formed by a combined action of all pinholes on each of the plurality of chips and the first deformation vector set. A physical meaning of the objective function ƒ is an average distance between the plurality of chips and the target matrix. A combined displacement state and the total displacement vector are obtained by subjecting the unit displacement vectors of each of the plurality of chips to addition. An offset of an actual position is determined by calculating the difference of the total displacement vector and the first displacement vector set. The offset of the position of each of the plurality of chips is increasingly smaller, indicating that an actual displacement is increasingly closer to the expected state and the value of the objective function is increasingly smaller. When iterating the objective function, an initialization is performed first. The position of the pinhole is moved to a circle serving an origin (the center of the wafer expansion ring 5) as the center and a radius of the wafer expansion ring 5 as the radius. Then, the iteration of the objective function is carried out 100 times. The coordinates of the pinholes are jumped, simultaneously iterating. When the value of the objective function ƒ keeps unchanged, the actual coordinates of the pinholes are recorded. This step effectively finds the optimal position of the pinhole by adjusting the positions of pinholes and simultaneously monitoring changes of the objective function. After each adjustment, the objective function is recalculated until a convergent state is reached (i.e., the value of the objective function changes slightly, indicating that it is close to the optimal solution).

In some embodiments, in step (S5), the step of adjusting the number of the pinhole according to the value of the objective function and the expected value is performed through the following steps.

The expected value is set.

If the value of the objective function is not less than the expected value, the number of the pinhole is increased.

If the value of the objective function is less than the expected value, the number of the pinhole is kept unchanged.

In some embodiments, the expected value is set to combine with the subsequent procedures. The expected value represents an acceptable maximum average distance between the plurality of chips and the target matrix. When the objective function value reaches or exceeds the expected value, the number of the pinhole is increased to meet requirements for the chip pitch control. Conversely, the actual number of the pinhole is maintained to avoid instability caused by excessive adjustment, and is automatically optimized under different conditions to ensure its response capability and stability. Meanwhile, the performance deficiency problems caused by fixed parameters are solved.

In some embodiments, the number of the pinhole is compared with the number of the plurality of chips. According to the comparison results, the target matrix is adjusted, and returning to step (S2), or step (S6) is performed.

If the number of the pinhole is less than one percent of the number of the chips, step (S6) is executed.

If the number of the pinhole is not less than one percent of the number of the plurality of chips, the chip pitch of the target matrix is increased, with returning to step (S2).

In an embodiment, if the number of the pinhole is less than one percent of the number of the plurality of chips, the number of the pinhole is normal, thereby executing step (S6); and if the number of the pinhole is not less than one percent of the number of the plurality of chips, the number of the pinhole is excessive and the solution time for the coordinates of the pinhole is greatly prolonged. Moreover, excessive pinholes can damage an internal stress on the wafer expansion ring 5, leading to changes in overall mechanical property of the wafer expansion ring 5 and making it unusable for the subsequent procedures.

In the embodiment, the chip pitch in the target matrix is adjusted from 0.40 mm to 0.41 mm, with returning to step (S2) to allow the plurality of chips to distribute more uniformly.

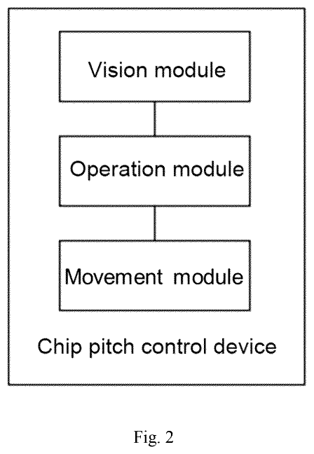

According to another embodiment in FIG. 2, a device for controlling chip pitch based on the film piercing includes a vision module, an operation module, and a movement module.

The vision module is configured to capture images of a plurality of chips and send the images of the plurality of chips to the operation module.

The operation module is configured to receive the images of the plurality of chips from the vision module, calculate coordinates of the plurality of chips with a center of a wafer expansion ring as an origin, and perform the following steps.
(S1) A first position matrix is generated according to position coordinates of each of the plurality of chips before the film piercing, and a target matrix of the plurality of chips is constructed according to the first position matrix.
(S2) A first displacement vector set of the plurality of chips is constructed according to the first position matrix and the target matrix.
(S3) A second displacement vector set is generated according to position coordinates of each of the plurality of chips after the film piercing and the first position matrix, and a unit displacement vector of each of the plurality of chips corresponding to a pinhole is obtained based on a quadratic spline interpolation method and the second displacement vector set.
(S4) An objective function is iterated according to unit displacement vectors of the plurality of chips and the first displacement vector set, and simultaneously coordinates of the pinhole are adjusted.
(S5) The number of the pinhole is adjusted according to a value of the objective function and an expected value, and is compared to the number of the plurality of chips. According to comparison results, the target matrix is adjusted, with proceeding to the subsequent steps, or the adjusted coordinates of the pinhole are sent to the movement module.

The movement module is configured to receive the adjusted coordinates of the pinhole from the operation module, and control a needle to pierce a back film according to the adjusted coordinates of the pinhole.

In an embodiment, the embodiment provides the device for controlling chip pitch based on the film piercing, which can also achieve the chip pitch control device shown in FIG. 3. Presented herein is the device for controlling chip pitch based on the film piercing to achieve the method for controlling chip pitch based on the film piercing and the corresponding implementation processes with reference to the above embodiment. For the sake of clarity, various possible combinations will not be described herein.

In the description of the present disclosure, the expressions involving reference terms such as “an embodiment”, “some embodiments”, “illustrative embodiments”, “examples”, “specific examples”, or “some examples”, refer to specific features, structures, materials or characters described with reference to the embodiments or the examples are included at least one the embodiment or example of the present disclosure. As used herein, the illustrative expressions of the above terms may not refer to the same embodiment or example. Moreover, specific features, structures, materials or characters can be combined with a proper manner in any one of or a plurality of the embodiments or examples.

Although the present disclosure has been described in detail above with reference to the embodiments, those skilled in the art can still make various modifications, changes and replacements to the features recited therein. It should be understood that any modifications, changes and replacements made without departing from the spirit and principle of the disclosure shall fall within the scope of the disclosure defined by the appended claims.

What is claimed is:

1. A method for controlling chip pitch based on film piercing, comprising:
(S1) generating a first position matrix according to position coordinates of each of a plurality of chips before film piercing, and constructing a target matrix of the plurality of chips according to the first position matrix;
(S2) constructing a first displacement vector set of the plurality of chips according to the first position matrix and the target matrix;
(S3) generating a second displacement vector set according to position coordinates of each of the plurality of chips after the film piercing and the first position matrix; and obtaining a unit displacement vector of each of the plurality of chips corresponding to a pinhole based on a quadratic spline interpolation method and the second displacement vector set;
(S4) iterating an objective function according to unit displacement vectors of the plurality of chips and the first displacement vector set, and simultaneously adjusting coordinates of the pinhole;
(S5) adjusting the number of the pinhole according to a value of the objective function and an expected value; comparing the number of the pinhole with the number of the plurality of chips; and according to comparison results, adjusting the target matrix and returning to step (S2), or proceeding to step (S6); and
(S6) controlling a needle to pierce a back film according to adjusted coordinates of the pinhole.

2. The method according to claim 1, wherein step (S1) comprises:
calculating the position coordinates of each of the plurality of chips before the film piercing with a center of a wafer expansion ring as an origin;
marking the position coordinates of each of the plurality of chips to generate the first position matrix; and
calculating an average chip pitch in a X-axis direction and an average chip pitch in a Y-axis direction based on the first position matrix, respectively; and constructing the target matrix of the plurality of chips based on the average chip pitch in the X-axis direction and the average chip pitch in the Y-axis direction with the origin as a center of the target matrix.

3. The method according to claim 2, further comprising:
after step (S3), determining whether it is needed to replace the needle through steps of:
obtaining a displacement vector of a first chip in the second displacement vector set in the X-axis direction;
if a length corresponding to the displacement vector of the first chip in the X-axis direction is greater than the average chip pitch in the X-axis direction or the average chip pitch in the Y-axis direction, replacing the wafer expansion ring, replacing the needle with another one with a smaller diameter, and returning to step (S1);
if the length corresponding to the displacement vector of the first chip in the X-axis direction is less than the average chip pitch in the X-axis direction or the average chip pitch in the Y-axis direction and greater than one fifth of the average chip pitch in the X-axis direction or the average chip pitch in the Y-axis direction, proceeding to step (S4); and
if the length corresponding to the displacement vector of the first chip in the X-axis direction is no more than one fifth of the average chip pitch in the X-axis direction or the average chip pitch in the Y-axis direction, replacing the wafer expansion ring, replacing the needle with another one with a smaller diameter, and returning to step (S1).

4. The method according to claim 1, wherein the step of obtaining the unit displacement vector of each of the plurality of chips corresponding to the pinhole based on the quadratic spline interpolation method and the second displacement vector set comprises:
obtaining the position coordinates of each of the plurality of chips before the film piercing and a displacement vector of each of the plurality of chips in the second displacement vector set; and
calculating coefficients of a spline curve between every two of the plurality of chips by using the quadratic spline interpolation method, satisfying the following relationship:
$$Δ {x}_{b i j} = {a}_{i} {x}_{1 i j}^{2} + {b}_{i} {x}_{1 ij} + {c}_{i} ;$$
wherein Δx_{bij} represents a displacement vector of a chip in an i-th row and a j-th column of the second displacement vector set; x₁ᵢⱼ represents an X-axis coordinate of the chip in the i-th row and the j-th column before the film piercing; and aᵢ, bᵢ and cᵢ represent the coefficients of the spline curve between every two of the plurality of chips.

5. The method according to claim 4, wherein the step of obtaining the unit displacement vector of each of the plurality of chips corresponding to the pinhole based on the quadratic spline interpolation method and the second displacement vector set further comprises:
obtaining a distance between each of the plurality of chips and the pinhole;
calculating a displacement of each of the plurality of chips after the film piercing according to the coefficients of the spline curve between every two of the plurality of chips and the distance between each of the plurality of chips and the pinhole, expressed as:
$$Δ x = {a}_{i} {d}^{2} + {b}_{i} d + {c}_{i} ;$$
wherein Δx represents the displacement of each of the plurality of chips after the film piercing; aᵢ, bᵢ and cᵢ represent the coefficients of the spline curve between every two of the plurality of chips; and d represents the distance between each of the plurality of chips and the pinhole; and
constructing the unit displacement vector based on the displacement of each of the plurality of chips after the film piercing and a direction from the pinhole to a corresponding one of the plurality of chips.

6. The method according to claim 1, wherein the step of iterating the objective function according to unit displacement vectors of the plurality of chips and the first displacement vector set, and simultaneously adjusting the coordinates of the pinhole comprises:
subjecting the unit displacement vectors to addition to generate a total displacement vector;
calculating an average distance between the plurality of chips and the target matrix according to the total displacement vector and the first displacement vector set, expressed as:
$$f = \frac{1}{n} \sum ‖ C - Δ A ‖ ;$$
wherein ƒ represents the objective function; C represents the total displacement vector; n represents the number of the plurality of chips; and ΔA represents the first displacement vector set; and
adjusting the coordinates of the pinhole until the objective function ƒ no longer changes, and recording adjusted coordinates of the pinhole.

7. The method according to claim 1, wherein in step (S5), the step of adjusting the number of the pinhole according to the value of the objective function and the expected value comprises:
setting the expected value;
if the value of the objective function is not less than the expected value, increasing the number of the pinhole; and
if the value of the objective function is less than the expected value, keeping the number of the pinhole unchanged.

8. The method according to claim 7, wherein the step of comparing the number of the pinhole with the number of the plurality of chips, and according to comparison results, adjusting the target matrix and returning to step (S2), or proceeding to step (S6) comprises:
if the number of the pinhole is less than one percent of the number of the plurality of chips, executing step (S6); and
if the number of the pinhole is not less than one percent of the number of the plurality of chips, increasing a chip pitch in the target matrix and returning to step (S2).

9. A device for controlling chip pitch based on film piercing, comprising:
a vision module;
an operation module; and
a movement module;
wherein the vision module is configured to capture images of a plurality of chips and send the images of the plurality of chips to the operation module;
the operation module is configured to receive the images of the plurality of chips from the vision module, calculate coordinates of the plurality of chips with a center of a wafer expansion ring as an origin, and perform steps of:
(S1) generating a first position matrix according to position coordinates of each of the plurality of chips before the film piercing, and constructing a target matrix of the plurality of chips according to the first position matrix;
(S2) constructing a first displacement vector set of the plurality of chips according to the first position matrix and the target matrix;
(S3) generating a second displacement vector set according to position coordinates of each of the plurality of chips after the film piercing and the first position matrix; and obtaining a unit displacement vector of each of the plurality of chips corresponding to a pinhole based on a quadratic spline interpolation method and the second displacement vector set;
(S4) iterating an objective function according to unit displacement vectors of the plurality of chips and the first displacement vector set, and simultaneously adjusting coordinates of the pinhole; and
(S5) adjusting the number of the pinhole according to a value of the objective function and an expected value; comparing the number of the pinhole with the number of the plurality of chips; and according to comparison results, adjusting the target matrix and returning to step (S2), or sending adjusted coordinates of the pinhole to the movement module; and
the movement module is configured to receive the adjusted coordinates of the pinhole from the operation module, and control a needle to pierce a back film according to the adjusted coordinates of the pinhole.
